(19) United States
(12) Patent Application Publication
(10) Pub. No.: US 2020/0043882 A1
(43) Pub. Date: Feb. 6, 2020

(54) BRAZE BONDED NAIL HEAD LEAD

(71) Applicants: Dean W. KICK, Oak Creek, WI (US); Paul Julien GAGNON, Narragansett, RI (US); David Lee WANDERV AART, San Marcos, CA (US); Lucas-Milhaupt, Inc., Cudahy, WI (US)

(72) Inventors: Dean W Kick, Oak Creek, WI (US); Paul Julien Gagnon, Narragansett, RI (US); David Lee VanDerVaart, San Marcos, CA (US)

(21) Appl. No.: 16/335,981

(22) PCT Filed: Sep. 22, 2017
(86) PCT No.: PCT/US2017/052975

§ 371 Date: Mar. 22, 2019

Related U.S. Application Data
(60) Provisional application No. 62/398,047, filed on Sep. 22, 2016.

(51) Int. Cl. H01L 23/00; B23K 9/167; B23K 9/00

(52) U.S. Cl. CPC H01L 24/78; H01L 24/85; B23K 9/167; B23K 9/0026; H01L 2224/78269; H01L 2224/85236; H01L 2924/01015; H01L 2924/01029; H01L 2924/01047; H01L 2224/85169; H01L 2224/7827

(57) ABSTRACT

A braze bonded nail head includes a nail head lead having a first end with first and second sides and a braze alloy preform coupled to the first side of the first end of the nail head lead The braze bonded nail head further includes a weld joint centrally located on the braze alloy preform and extending through the braze alloy preform to the first end of the nail head lead. The weld joint is formed through micro-tig-welding, in alternative embodiments of the invention, one of the nail head lead and the braze alloy preform may include at least one protrusion extending therefrom, while the other of the nail head lead and the braze alloy preforms may include at least one interfit element configured to interfit with the at least one protrusion.

### CROSS-REFERENCE TO RELATED APPLICATION

This application claims priority to U.S. Provisional Application No. 62/398,047, filed on Sep. 22, 2016, the entire contents of which are each hereby expressly incorporated by reference into this application.

### BACKGROUND OF THE INVENTION

### 1. Field of the Invention

The present invention relates to a braze bonded nail head lead, wherein the nail head lead and braze alloy preform are formed into a single use part for brazing.

### 2. Discussion of the Related Art

Nail head leads and brazing discs are currently used in conjunction in the diode industry to facilitate brazing a nail head lead to a semiconductor chip. Conventional diode manufacturing is done by attaching a nail head lead 10 made of copper or silver to a molybdenum or tungsten stud joined to chip assembly 12 using a brazing disc 14 made from an alloy of silver, copper, and sometimes phosphorus. The assembly requires placing the components into a ceramic package 16, and then into a vacuum brazing operation as depicted in FIG. 1.

As shown in FIG. 1, the nail head lead 10, the braze disc 14, and the semiconductor chip 16 are aligned as separate pieces in order to braze the diode assembly 18. However, failure to correctly align the nail head lead 10 and the braze disc 14 can result from loading mistakes or movement of the diode assembly within the brazing process. Such failure can lead to yield loses or braze part rejection rates as high as 25% failure.

As such, there is a need in the art for a braze bonded nail head lead having a braze preform fastened to a nail head lead prior to manufacturing of the diode assembly, in order to improve efficiency, quality, and cost. Furthermore, the proposed manufacturing process aims to couple the nail head lead and the braze preform so as not to distort the braze preform having a thickness between 0.0015 and 0.003 inches.

In particular, welding techniques for bonding such a small braze preform would result in distortion of the braze preform by virtue of the heat effected zone of the weld spot. Such distortion results in a braze disc that would no longer lay flat. In addition, entrapment of gases common to welding would result in bond imperfections that would interfere with the functionality of the braze bond.

### SUMMARY OF THE INVENTION

A braze bonded nail head lead wherein the nail head lead formation, the braze alloy preform formation, and the coupling of the braze disc preform to the nail head lead occur in subsequent steps.

In accordance with an embodiment of the invention, a braze bonded nail head includes a nail head lead having a first end and a braze alloy preform coupled to the first end of the nail head lead. Further, the nail head lead and the braze alloy preform are permanently coupled together by way of a weld joint to form a single use part for assembly brazing. According to one aspect of the invention, the weld joint is formed by way of micro-tig welding.

According to another aspect of the invention, one of the nail head lead and the braze alloy preform includes at least one protrusion extending therefrom, while the other of the nail head lead and the braze alloy preforms includes at least one interfit element configured to interfit with the at least one protrusion.

According to yet another aspect of the invention, at least one protrusion includes a center post extending from a first side of the first end of the nail head lead, and the at least one interfit element comprises an orifice formed in the center of the braze alloy preform. The orifice is configured to interfit with the center post.

In accordance with another embodiment of the invention, a method of manufacturing a braze bonded nail head lead includes providing a wire, forming the wire into a nail head lead, aligning the nail head lead with a braze alloy preform, stamping the braze alloy preform on the first side of the first end of the nail head lead, and coupling the braze alloy preform to a first side of the first end of the nail head lead by way of a weld joint. Forming the wire into a nail head lead includes forming a first end having the first side and a second side and a shaft extending from the second side of the first end.

According to one aspect of the invention, coupling the braze alloy preform to the first side of the first end of the nail head lead by way of a weld joint comprises precision micro-tig-welding the braze alloy preform to the first end of the nail head lead.

According to another aspect of the invention, the method further includes forming at least one protrusion on one of the first end of the nail head lead and the braze alloy preform, and forming at least one interfit element on the other of the first end of the nail head lead and the braze alloy preform. The at least one protrusion is configured to interfit with the at least one interfit element.

In accordance with yet another embodiment of the invention, a braze bonded nail head lead includes a nail head lead having a first end with a first side and a second side, a braze alloy preform coupled to the first side of the first end of the nail head lead, and a weld joint centrally located on the braze alloy preform and extending through the braze alloy preform to the first end of the nail head lead. The nail head lead also includes a shaft extending from a second side of the first end of the nail head lead. According to one aspect of the invention, the weld joint is formed via precision micro-tig-welding.

According to another aspect of the invention, the nail head lead includes a protrusion extending from the first end of the nail head lead, and the braze alloy preform includes an interfit element formed therethrough and configured to interfit with the protrusion of the nail head lead. A diameter of the protrusion and a diameter of the interfit element are approximately the same so that the braze alloy preform and the nail head lead are coupled to each other when the protrusion and the interfit element.

These and other aspects and objects of the present invention will be better appreciated and understood when considered in conjunction with the following description and the accompanying drawings. It should be understood, however, that the following description, while indicating preferred embodiments of the present invention, is given by way of illustration and not of limitation. Many changes and modifications may be made within the scope of the present invention without departing from the spirit thereof, and the invention includes all such modifications. Further, although many methods and materials similar or equivalent to those described herein may be used in the practice of the present invention, a few such suitable methods and materials are described in greater detail below.

### BRIEF DESCRIPTION OF THE DRAWINGS

A clear conception of the advantages and features constituting the present invention, and of the construction and operation of typical mechanisms provided with the present invention, will become more readily apparent by referring to the exemplary, and therefore non-limiting, embodiments illustrated in the drawings accompanying and forming a part of this specification, wherein like reference numerals designate the same elements in the several views, and in which:

FIG. 1 is a schematic view of conventional diode manufacturing, according to the prior art;

FIG. 2 is a side view of a nail head lead, according to an embodiment of the invention;

FIG. 3 is a perspective view of a braze bonded nail head lead, according to an embodiment of the invention;

FIG. 4 is a side view of a nail head lead, according to another embodiment of the invention;

FIG. 5 is a perspective view of a braze bonded nail head lead including the nail head lead of FIG. 4, according to an embodiment of the invention;

FIG. 6 is a perspective view of a braze bonded nail head lead, according to yet another embodiment of the invention;

FIG. 7 is a perspective view of a braze bonded nail head lead, according to yet another embodiment of the invention;

FIG. 8 is a perspective view of a braze bonded nail head lead, according to yet another embodiment of the invention;

FIG. 9 is a block diagram of a method of coupling a braze alloy preform to a nail head lead to form braze a braze bonded nail head lead, according to an embodiment of the invention.

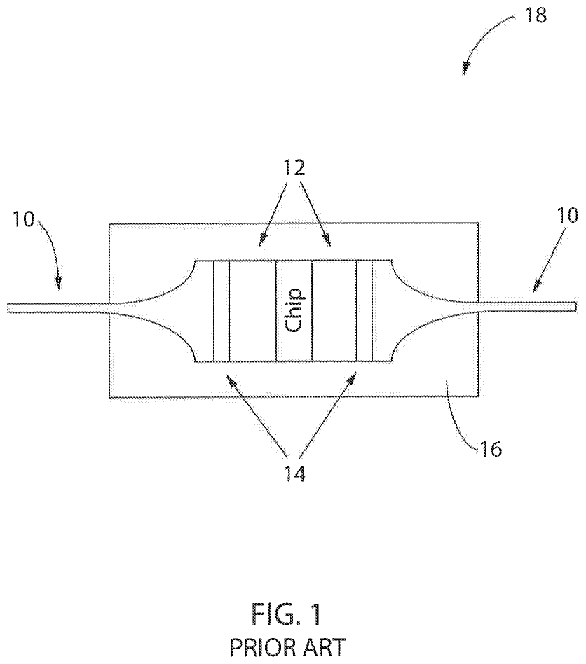

In describing the preferred embodiment of the invention which is illustrated in the drawings, specific terminology will be resorted to for the sake of clarity. However, it is not intended that the invention be limited to the specific terms so selected and it is to be understood that each specific term includes all technical equivalents which operate in a similar manner to accomplish a similar purpose.

### DETAILED DESCRIPTION OF THE DRAWINGS

The present invention and the various features and advantageous details thereof are explained more fully with reference to the non-limiting embodiments described in detail in the following description.

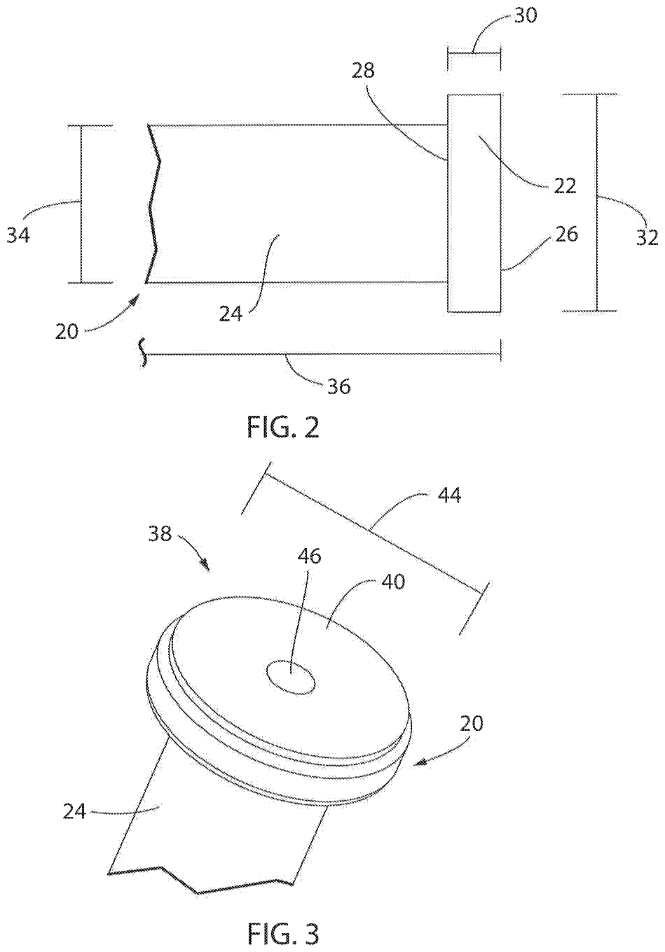

First referring to FIG. 2, a side view of a nail head lead 20 having a first end 22 and a shaft 24 extending from the first end 22. In the representative embodiment of the invention, the first end 22 includes a first side 26 and a second side 28, and the shaft 24 extends from the second side 28 of the first end 22. As shown in greater detail in FIG. 3, the first end 22 of the nail head lead 20 may be in the shape of a disc having a thickness 30 ranging from 0.007 to 0.015 inches±0.002 inches. The first end 22 of the nail head lead 20 may include an outer diameter 32 ranging from 0.030 to 0.150 inches±0.002 inches. Further, a diameter 34 of the shaft 24 may range from 0.020 to 0.060 inches±0.001 inches. Additionally, the nail head lead 20 may have a length 36 ranging from 0.55 to 1.10 inches±0.010 inches. In alternative embodiments of the invention, the first end 22 of the nail head lead 20 may be in a shape other than a disc.

Next, FIG. 3 illustrates a perspective view of a braze bonded nail head 38. The braze bonded nail head lead 38 includes the nail head lead of FIG. 2 coupled to a braze alloy preform 40. The braze alloy preform 40 is in the form of a disc. In the representative embodiment of the invention, the braze alloy preform 40 has a thickness of the braze alloy preform 26 may range from 0.0015 to 0.003 inches. While the representative embodiment of the invention illustrates the braze alloy preform 40 as having a diameter 44 less than the diameter 32 of the first end 22 of the nail head lead 20, it is contemplated that the diameter 44 of the braze alloy preform 40 may be greater than, less than, or equal to the diameter 32 of the first end 22 of the nail head lead 20. In other embodiments of the invention, the braze alloy preform 40 may be in a shape other than a disc.

As will be described later, the braze alloy preform 40 is stamped on the first side 26 of the first end 22 of the nail head lead 20. Subsequently, the braze alloy preform 40 and the nail head lead 20 are coupled together via a joint 46 formed by welding. In the representative embodiment of the invention, the joint 46 is centrally located on the braze alloy preform 40 and extends through the braze alloy preform 40 to the first end 22 of the nail head lead 20 in order to permanently couple the braze alloy preform 40 to the nail head lead 20.

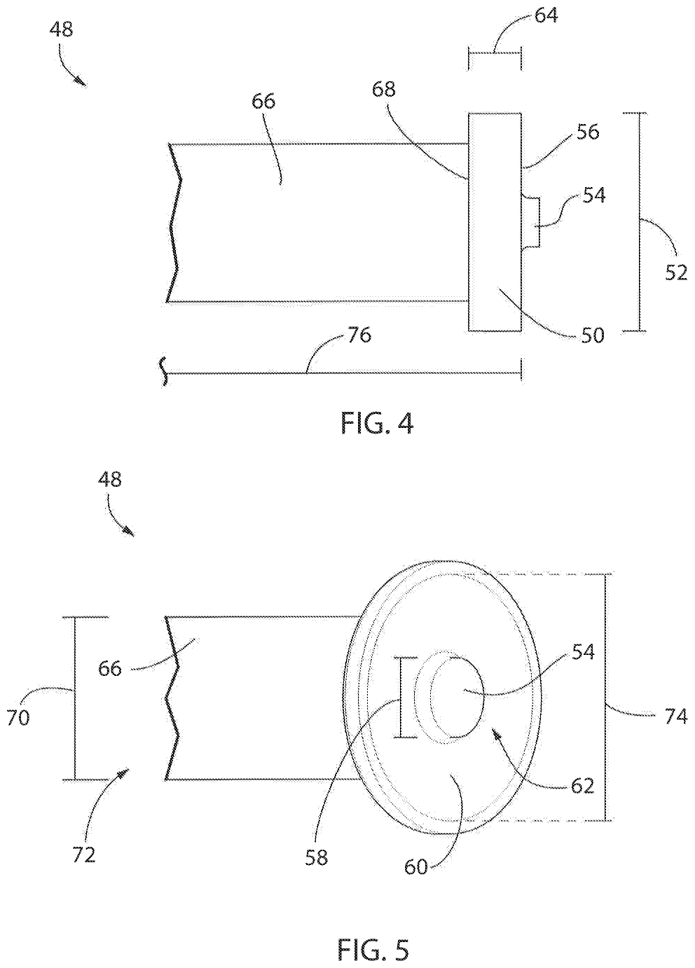

Now referring to FIG. 4, a side view of a nail head lead 48 having a first end 50 is shown, according to another embodiment of the invention. In the representative embodiment of the invention, the first end 22 of the nail head lead 20 is in the shape of a disc having a diameter 52 ranging from 0.030 to 0.150 inches±0.002 inches. In this representative embodiment of the invention, a protrusion 54 is formed on a first side 56 of the first end 22 of the nail head lead 20. In the representative embodiment of FIG. 2, the protrusion 54 is a center post extending beyond the first side 56 of the first end 50 of the nail head lead 48. It is contemplated that a diameter 58 of the center post 54 may range from 0.010 to 0.050 inches. Other embodiments of the invention will be described later, in which the protrusion 54 may take other forms. In yet other embodiments of the invention, the protrusion 54 may be formed on a braze alloy preform 60 and the first end 50 of the nail head lead 48 is formed to include an interfit element 62.

In representative embodiments of the invention, the first end 50 of the nail head lead 48 may have a thickness 64 ranging from 0.007 to 0.015 inches±0.002 inches. The nail head lead 48 also includes a shaft 66 extending from a second side 68 of the first end 22 of the nail head lead 20. The nail head lead 48 may have a length 76 ranging from 0.55 to 1.10 inche±0.010 inches. In addition, the shaft 66 may have a diameter 70 ranging from 0.020 to 0.060 inches±0.001 inches.

As shown in FIG. 5, the nail head lead 48 is coupled to the braze alloy preform 60 to form a braze bonded nail head lead 72. While braze alloy preform 60 is illustrated as a disc throughout the representative embodiments of this application, it is contemplated that the braze alloy preform 60 is not limited to a disc shape in any of the embodiments of the invention. It is contemplated that a diameter 74 of the braze alloy preform 60 may range from 0.030 to 0.150 inches. It is further contemplated that a thickness of the braze alloy preform 60 may range from 0.0015 to 0.003 inches. In this representative embodiment of the invention, the braze alloy preform 60 includes an interfit element 62 configured to interfit with the previously discussed protrusion 54 of the nail head lead 48. In this instance, the interfit element 62 is in the form of an orifice formed through the center region of the braze alloy preform 60 configured to interfit with the center post 54 of FIG. 4. The diameter 58 of the center post 54 and a diameter of the orifice 62 are approximately the same so that the braze alloy preform 60 and the nail head lead 48 are permanently coupled to each other when the center post 54 interfits with the orifice 62.

While FIG. 5 depicts the braze alloy preform 60 as being flush with the first side 56 of first end 50 of the nail head lead 48, the braze alloy preform 60 may extend beyond the first side 56 of the first end 50 of the nail head lead 48, in alternative embodiments of the invention. As such, it is contemplated that the braze disc 60 may be either flush with or extend beyond the first side 56 of the first end 50 of the nail head lead 48.

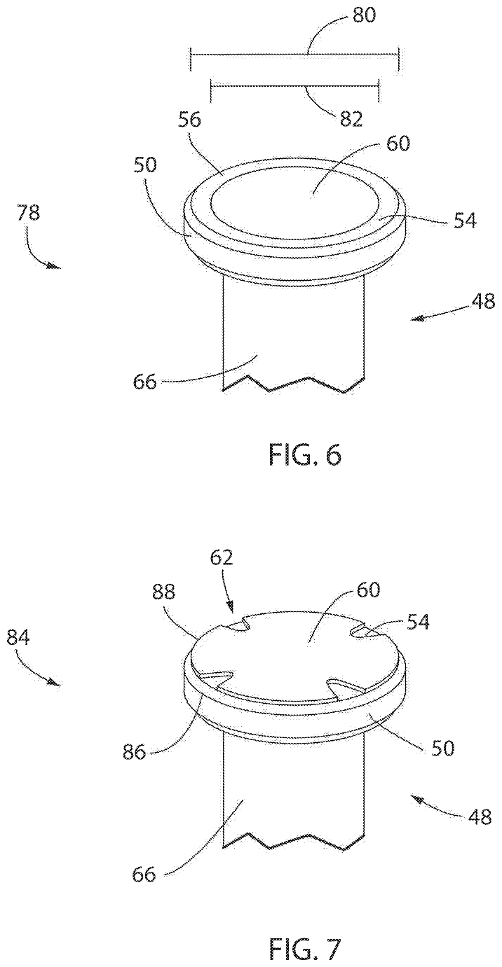

Next, FIG. 6 depicts a braze bonded nail head lead 78 according to another embodiment of the invention. In this instance, the nail head lead 48 includes a protrusion 54 in the form of an outer ridge formed on the first side 56 of the first end 50 of the nail head lead 48. In turn, the braze alloy preform 60 is configured to interfit within the outer ridge 54. It is contemplated that an outer diameter 80 of the outer ridge 54 ranges from 0.030 to 0.150 inches and an inner diameter 82 of the outer ridge 24 ranges from 0.020 to 0.140 inches.

Next, FIG. 7 illustrates a braze bonded nail head lead 84, according to yet another embodiment of the invention. In this instance, the nail head lead 48 includes a plurality of protrusions 54 that extend along the first side 56 of the first end 50 of the nail head lead 48. As shown in FIG. 7, the plurality of protrusions 54 extend inwardly from a rim 86 of the nail head lead 48 and along the first side 56 of the first end 50 of the nail head lead 48. In turn, the braze alloy preform 60 includes a plurality of interfit elements 62 disposed along an outer edge 88 of the braze alloy preform 60. In the representative embodiment of the invention, the plurality of interfit elements 62 are in the form of notches along the outer edge 88 of the braze alloy preform 60. Each notch 62 is configured to interfit with a respective one of the plurality of protrusions 54.

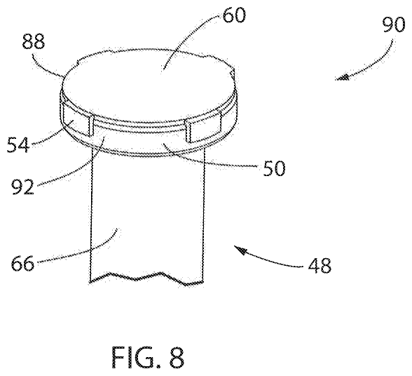

FIG. 8 shows a braze bonded nail head lead 90, according to yet another embodiment of the invention. In this embodiment of the invention, the braze alloy preform 60 includes a plurality of protrusions 54. The protrusions 54 extend downward from the outer edge 88 of the braze alloy preform 60. Further, the protrusions 54 are configured to interfit with an outer edge 92 of the first end 50 of the nail head lead 48.

In the representative embodiment of the invention, each nail head lead may be formed using a 4-slide machine which includes a second slide that engages to grip a wire and advance it into a die zone, a third slide that engages to form the wire into a nail head lead, and a fourth slide that engages to cut the finished nail head lead to size. When completed, all slides open and the finished nail head lead is ejected. A braze alloy preform may then be coupled to finished the nail head lead.

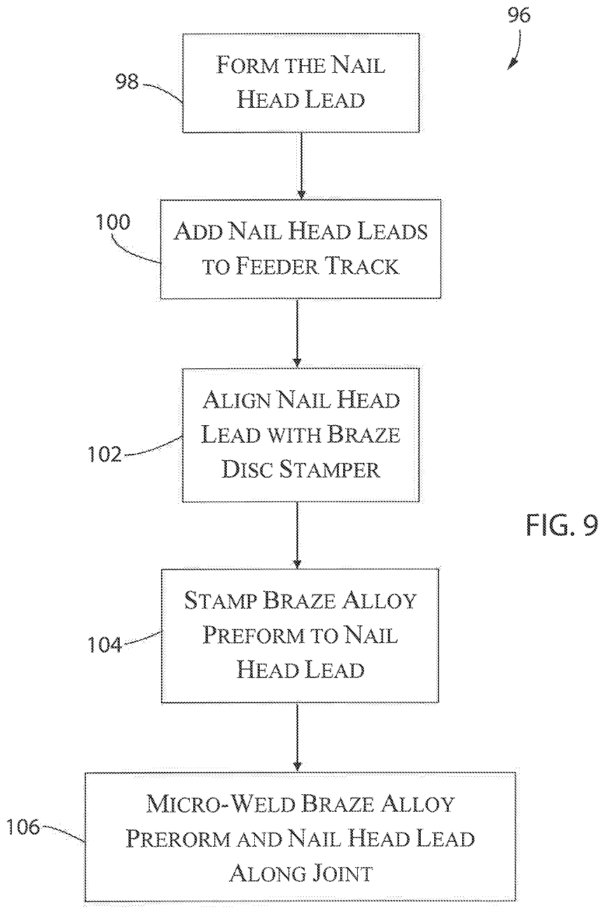

With respect to the embodiment shown in FIGS. 2 and 3, the braze alloy preform 26 may be coupled to the nail head lead 20 after the braze alloy preform 26 and the nail head lead 20 have been formed. Such a method will be later described with respect to FIG. 9.

In alternative embodiments of the invention, such as those shown in FIGS. 4-8, formation of the nail head lead 48 includes formation of one of at least one protrusion 54 or at least one interfit element 62 on the first end 56 of the nail head lead 48, formation of the braze alloy preform 60 includes formation a corresponding one of at least one interfit element 62 and at least one protrusion 54 on the braze alloy perform 60, and coupling of the braze alloy preform 60 and the nail head lead 48 includes interfitting the at least one protrusion 54 with the at least one interfit element 62. As described above, the diameter 58 of the protrusion 54 and the diameter 94 of its respective interfit element 62 are approximately the same so that the braze alloy preform 60 and the nail head lead 48 are permanently coupled to each other when the protrusion 54 and the interfit element 62 interfit. Now referring to the embodiment illustrated in FIG. 6, formation of the nail head lead 48 includes formation of the outer ridge 54, formation of the braze alloy preform 60 includes sizing the braze alloy preform 60 to fit within the outer ridge 54, and coupling the braze alloy preform 60 to the nail head lead 48 includes interfitting the braze alloy preform 60 within the outer ridge 54.

In regard to the embodiment depicted in FIG. 7, formation of the nail head lead 48 includes formation of the plurality of protrusions 54 along the rim 86 of the first end 50 of the nail head lead 48, formation of the braze alloy preform 60 includes formation of the notches 62 configured to align with the protrusions 54, and coupling the braze alloy preform 60 to the nail head lead 48 includes interfitting a respective one of the protrusions 54 into each notch 62.

Further, in the embodiment shown in FIG. 8, formation of the nail head lead 48 includes formation of the first end 50 of the nail head lead 48, formation of the braze alloy preform 60 includes formation of the protrusions 54 that extend downward from the outer edge 88 of the braze alloy preform 60, and coupling the braze alloy preform 60 to the nail head lead 48 includes interfitting the first end 50 of the nail head lead 48 within the protrusions 54 of the braze alloy preform 60.

In alternative embodiments of the invention, the braze alloy preform 26 may be coupled to the nail head lead 20 via an adhesive, 3-D printing, electroplating, direct cladding, and other coupling methods. Additionally, braze alloy preforms 26 and nail head leads 20 using these alternative coupling methods may or may not include protrusions 24 and interfit elements as described above.

In some embodiments of the invention, the nail head lead 48 is formed, the braze alloy preform 60 is formed, and the nail head lead 48 and the braze alloy preform are coupled together in a single simultaneous step. In other embodiments of the invention, each formation and coupling step may be performed separately.

It is further contemplated that in other embodiments of the invention, protrusions 54 and interfit elements 62 such as those shown in FIGS. 4-8 may be used in conjunction with the welding joint 46 resulting from the method illustrated in FIG. 9 and described below.

In the representative embodiments of the invention, it is contemplated that the nail head lead 20, 48 comprises at least one of silver or copper. However, it is also contemplated that other materials known in the art may be used as well. Similarly, while the representative embodiments of the invention include a braze alloy preform 40, 60 comprising an alloy of at least one of silver and copper and phosphorus, it is also contemplated that other materials known in the art may also be used.

Now referring to FIG. 9, a method 96 is shown depicting forming the braze bonded nail head lead 20 of FIG. 3, according to an embodiment of the invention. In step 98, the nail head lead may be formed as described above and into the shape of the nail head lead 20 shown in FIG. 3. In alternative embodiments of the invention, the nail head lead may be formed to into the shapes of the nail head lead 48 shown in FIGS. 4-8 to include at least one protrusion 54 or at least one interfit element 62 configured to interfit with at least one interfit element 62 or at least one protrusion 54, respectively, of the braze alloy preform 60. In yet other embodiments of the invention, the nail head lead 48 may be formed to include a combination of at least one protrusion and at least one interfit element configured to interfit with respective interfit elements and protrusions, respectively, of the braze alloy preform 60.

In step 100, the nail head leads are oriented first end up in a feeder track, such as a bowl feeder. As the feeder track moves the nail head leads through the system, each nail head lead is aligned underneath a braze disc stamping tool, which includes braze alloy preform. In step 102, the braze disc stamping tool stamps a braze alloy preform onto the first side of the first end of the nail head lead. In one embodiment of the invention, the feeder track includes a holder for each nail head lead that is configured to receive the braze alloy preform and maintain its position on the first end of the nail head lead. In embodiments of the invention using the nail head leads 48 shown in FIGS. 4-8, each braze alloy preform 60 is stamped on its respective nail head lead 48 so that the each of the at least one protrusion 54 interfits with its respective interfit element 62.

In one embodiment of the invention, the braze disc stamping tool is configured to receive a pancake coil of strip comprising the material of the braze alloy preform. Subsequent to stamping the braze alloy preform onto the first side of the first end of the nail head lead, the braze disc stamping tool cuts the braze alloy preform from the pancake coil of strip.

Next, step 104 feeds the nail head lead and its respective braze alloy preform to a micro-welding location. In step 106, the braze alloy preform and the nail head lead are micro-welded to form the joint 46. While FIG. 3 illustrates a resulting braze bonded nail head lead 38 having a joint 46 centrally located on the braze alloy preform 40, it is contemplated that the joint 46 may be located anywhere along the braze alloy preform 40 to properly couple the braze alloy preform 40 to the nail head lead 20. In the representative embodiment of the invention, the micro-welding procedure is precision micro-tig-welding, so as not to distort the braze alloy preform.

The above described process and later brazing process may be performed in a vacuum setting. However, it is also contemplated that either process may be performed in an atmosphere setting. In an atmosphere setting, a flux may be used to prepare the surfaces to be joined.

Other objects, features and advantages of the present invention will be apparent to those skilled in the art. The invention described herein is not limited in any manner by the descriptions, definitions or characteristics of any brazing material or the metals or alloys or ceramics that may be joined thereby, of any flux composition. Any brazing flux or brazing material may be used for the purposes of the invention.

It is specifically intended that the present invention not be limited to the embodiments and illustrations contained herein, but includes modified forms of those embodiments including portions of the embodiments and combinations of elements of different embodiments as come within the scope of the following claims.

1. A braze bonded nail head comprising:
a nail head lead having a first end;
a braze alloy preform coupled to the first end of the nail head lead; and
wherein the nail head lead and the braze alloy preform are permanently coupled together by way of at least one of a weld joint and an interfit joint to form a single use part for assembly brazing.

2. The braze bonded nail head lead of claim 1 wherein the weld joint is formed through micro-tig-welding.

3. The braze bonded nail head lead of claim 1 wherein the interfit joint is formed by at least one protrusion of one of the nail head lead and the braze alloy preform interfitting with at least one interfit element of the other of the nail head lead and the braze alloy preform.

4. The braze bonded nail head of claim 3 wherein the at least one protrusion comprises a center post extending from a first side of the first end of the nail head lead; and
wherein the at least one interfit element comprises an orifice formed in the center of the braze alloy preform, the orifice configured to interfit with the center post.

5. The braze bonded nail head of claim 1 wherein a diameter of the first end of the nail head lead is between 0.030 and 0.150 inches.

6. The braze bonded nail head of claim 1 wherein a diameter of the braze alloy preform is between 0.030 and 0.150 inches.

7. The braze bonded nail head lead of claim 1 wherein a thickness of the braze alloy preform is between 0.0015 to 0.003 inches.

8. A method of manufacturing a braze bonded nail head lead comprising:
providing a wire;
forming the wire into a nail head lead, wherein forming the wire into a nail head lead includes forming a first end having a first side and a second side and a shaft extending from the second side of the first end;
aligning the nail head lead with a braze alloy preform;
stamping the braze alloy preform on the first side of the first end of the nail head lead; and
coupling the braze alloy preform to the first side of the first end of the nail head lead by way of a weld joint.

9. The method of claim 8 wherein coupling the braze alloy preform to the first side of the first end of the nail head lead by way of a weld joint comprises precision micro-tig-welding the braze alloy preform to the first end of the nail head lead.

10. The method of claim 8 further comprising:
forming at least one protrusion on one of the first end of the nail head lead and the braze alloy preform;
forming at least one interfit element on the other of the first end of the nail head lead and the braze alloy preform;
wherein the at least one protrusion is configured to interfit with the at least one interfit element.

11. The method of claim 8 wherein a diameter of the first end of the nail head lead is between 0.030 and 0.150 inches.

12. The method of claim 8 wherein a diameter of the braze disc is between 0.030 and 0.150 inches.

13. The method of claim 8 wherein a thickness of the braze alloy preform is between 0.0015 to 0.003 inches.

14. A braze bonded nail head lead comprising:
a nail head lead having a first end with a first side and a second side and a shaft extending from a second side of the first end;
a braze alloy preform coupled to the first side of the first end of the nail head lead; and
a weld joint centrally located on the braze alloy preform and extending through the braze alloy preform to the first end of the nail head lead.

15. The braze bonded nail head lead of claim 14 wherein the weld joint is formed via precision micro-tig-welding.

16. The braze bonded nail head lead of claim 14 wherein the nail head lead includes a protrusion extending from the first end of the nail head lead; and
wherein the braze alloy preform include an interfit element formed therethrough and configured to interfit with the protrusion of the nail head lead.

17. The braze bonded nail head lead of claim 14 wherein a diameter of the protrusion and a diameter of the interfit element are approximately the same so that the braze alloy preform and the nail head lead are coupled to each other when the protrusion and the interfit element interfit.

18. The braze bonded nail head of claim 14 wherein a diameter of the first end of the nail head lead is between 0.030 and 0.150 inches.

19. The braze bonded nail head of claim 14 wherein a diameter of the braze alloy preform is between 0.030 and 0.150 inches.

20. The braze bonded nail head lead of claim 14 wherein a thickness of the braze alloy preform is between 0.0015 to 0.003 inches.
